(19) United States
(12) Patent Application Publication
(10) Pub. No.: US 2009/0006104 A1
(43) Pub. Date: Jan. 1, 2009

(54) METHOD OF CONFIGURING CODEC AND CODEC USING THE SAME

(75) Inventors: Ho-sang Sung, Yongin-si (KR); Eun-mi Oh, Seongnam-si (KR); Kyung-hun Jung, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/954,111

(22) Filed: Dec. 11, 2007

(30) Foreign Application Priority Data
Jun. 29, 2007 (KR) 2007-65687

(51) Int. Cl. G10L 19/00; H03M 7/38

(52) U.S. Cl. 704/500; 341/51; 704/E19.001

(57) ABSTRACT

Provided is a codec that may be configured to adaptively optimize to various service environments by obtaining information on a current operating environment of the codec and configuring the codec in view of quality of service (QoS) parameters based on the obtained information.

### CROSS-REFERENCE TO RELATED APPLICATIONS

This application claims the benefit of Korean Patent Application No. 10-2007-0065687, filed on Jun. 29, 2007, in the Korean Intellectual Property Office, the disclosure of which is incorporated herein in its entirety by reference.

### BACKGROUND OF THE INVENTION

1. Field of the Invention

The present general inventive concept relates to a codec, and more particularly, to a method of configuring a codec and a codec using the same.

2. Description of the Related Art

A codec is a device or program that compresses and reproduces video, speech, and audio data. The word codec is an abbreviation for coder-decoder. A codec used in a computer may convert video, speech, and audio data into digital data that can be processed and transmitted by the computer, and may convert digital data into signals that can reproduce the video, speech, and audio data on the computer so as to be viewed or listened to by a user.

FIG. 1 is a block diagram of a conventional system including an adaptive multi-rate (AMR) codec.

Referring to FIG. 1, the conventional system includes a transcoding rate and adaptation unit (TRAU) 11, a base station 12, and a mobile station 13, and is used in a global system for mobile communication (GSM). GSM is a digital mobile phone standard that is widely used in Europe and other regions. GSM digitalizes and compresses data, and transmits the digitalized and compressed data through a channel together with two other pieces of user data. Each piece of data is transmitted at a specific time.

An uplink measurement unit 121 of the base station 12 measures the state of an uplink (UL) and a downlink measurement unit 131 of the mobile station 13 measures the state of a downlink (DL). Here, the uplink is a transmission path from the mobile station 13 to the base station 12, and is indicated by a dashed line. The downlink is a transmission path from the base station 12 to the mobile station 13, and is indicated by a solid line.

Conventional coding by a codec includes source coding by a source encoder (SPE) and channel coding by a channel encoder (CHE). In a complementary manner, the conventional decoding of a codec includes channel decoding by a channel decoder (CHD) and source decoding by a source decoder (SPD).

In the conventional system, bit rates used in the source coding and the channel coding are controlled according to information on the state of the uplink measured by the uplink measurement unit 121, and information on the state of the downlink measured by the downlink measurement unit 131. The source coding comprises compressing data by modeling human sensory characteristics and is performed by dividing the data into a human perceivable part and a human unperceivable part, and reducing or removing the human unperceivable part. The channel coding is also referred to as error correction coding (ECC) and is performed by adding new data to original data prior to data transmission so that a receiver can detect and correct an error caused by noise generated in a transmission channel.

Due to the convergence of technologies and functions, a terminal having various integrated functions, as opposed to having only one main function, is in strong demand. Accordingly, multiple codecs providing various services can be included in a single terminal.

Quality of service (QoS) of the various services is defined as a set of quality requirements to be satisfied for appropriate data transmission in a network. By satisfying QoS, for example, in a real-time program, an appropriate network bandwidth may be secured and network resources may be appropriately maintained. Thus, a common network may provide a level of services as high as the level of services in a dedicated network.

However, the conventional system illustrated in FIG. 1 may only control bit rates based on information on statuses of the uplink and downlink and thus may not be adaptable to various service environments.

### SUMMARY OF THE INVENTION

The present general inventive concept provides a method of appropriately configuring a codec according to a current status by adaptively controlling quality of service (QoS) parameters of various service environments.

The present general inventive concept also provides a codec appropriately configured according to a current status by adaptively controlling QoS parameters of various service environments.

Additional aspects and utilities of the present general inventive concept will be set forth in part in the description which follows and, in part, will be obvious from the description, or may be learned by practice of the general inventive concept.

The foregoing and/or additional aspects and utilities of the present general inventive concept can be achieved by providing a method of configuring a codec including obtaining information on a current operating environment of the codec, and configuring the codec in view of through quality of service (QoS) parameters based on the obtained information.

The foregoing and/or additional aspects and utilities of the present general inventive concept can also be achieved by providing a computer readable recording medium having recorded thereon a computer program that, when executed by a computer, performs a method of configuring a codec, the method including obtaining information on a current operating environment of the codec, and configuring the codec through quality of service (QoS) parameters thereof based on the obtained information.

The foregoing and/or additional aspects and utilities of the present general inventive concept can also be achieved by providing a method of configuring a codec, the method including initially configuring the codec by determining initial values of quality of service (QoS) parameters based on information on a network connected to the codec and at least one of information on a terminal having the codec, information on input data of the codec, and information on output data of the codec, and reconfiguring the codec by adaptively controlling the QoS parameters based on variations of the information on the network and at least one of the information on the terminal, the information on the input data, and the information on the output data.

The foregoing and/or additional aspects and utilities of the present general inventive concept can also be achieved by providing a method of configuring a codec, the method including initially configuring the codec by determining initial values of quality of service (QoS) parameters based on at least one of information on a terminal having the codec, information on input data of the codec, and information on output data of the codec, and reconfiguring the codec by adaptively controlling the QoS parameters based on variations of at least one of the information on the terminal, the information on the input data, and the information on the output data.

The foregoing and/or additional aspects and utilities of the present general inventive concept can also be achieved by providing a codec including a configuration setting unit to configure the codec in view of quality of service (QoS) parameters based on information on a current operating environment of the codec, a source encoder to encode first data in accordance with the configuration of the codec, and a source decoder to decode second data in accordance with the configuration of the codec.

The foregoing and/or additional aspects and utilities of the present general inventive concept can also be achieved by providing a method of configuring a codec in a variable operational environment, the method including determining a state of at least one characteristic of the operational environment from other than a communication link of a network that can be altered by an operation of the codec, and modifying the operation of the codec to alter the determined characteristic to achieve a predetermined quality of service in the operational environment.

The foregoing and/or additional aspects and utilities of the present general inventive concept can also be achieved by providing a codec to encode and decode signals in a variable operational environment, the codec including a mode information analysis unit to determine a state of at least one characteristic the operational environment from other than a network link that can be altered, and a configuration setting unit to receive the state of the characteristic and generate signals to modify an operation on one of input data, output data, downlink data and uplink data according to the determined state.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a block diagram of a conventional system including an adaptive multi-rate (AMR) codec;

FIG. 2 is a schematic diagram to describe a method of reconfiguring a codec according to an exemplary embodiment of the present general inventive concept;

FIG. 3 is a block diagram of a system including a reconfigurable codec illustrated in FIG. 2 according to an exemplary embodiment of the present general inventive concept;

FIG. 4 is a detailed block diagram of the reconfigurable codec illustrated in FIG. 3 according to an exemplary embodiment of the present general inventive concept;

FIG. 5 is a flowchart illustrating a method of configuring a codec according to an exemplary embodiment of the present general inventive concept; and

FIG. 6 is a flowchart illustrating a method of configuring a codec according to another exemplary embodiment of the present general inventive concept.

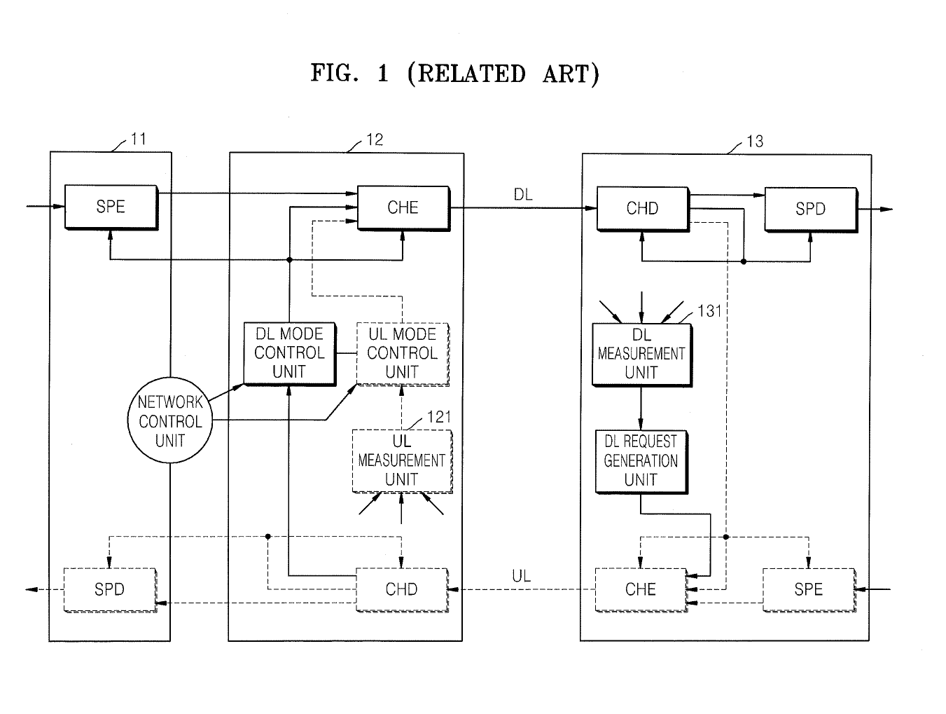

### DETAILED DESCRIPTION OF THE PREFERRED EMBODIMENTS

Structural and functional descriptions are provided to describe exemplary embodiments of the present general inventive concept, which may be embodied in many different forms and should not be construed as being limited to the embodiments set forth herein.

The present general inventive concept will now be described more fully with reference to the accompanying drawings, in which exemplary embodiments of the general inventive concept are illustrated. The exemplary embodiments should be considered in a descriptive sense only and not for purposes of limitation. Additionally, alternative embodiments not described herein but within the claimed scope are to be construed as being encompassed by the present general inventive concept.

Unless defined differently herein, all terms used in the description, including technical and scientific terms, have the same meaning as generally understood by those of ordinary skill in the art. Terms as defined in a commonly used dictionary should be construed as having the same meaning as in an associated technical context unless explicitly defined otherwise in the description.

Hereinafter, exemplary embodiments of the present general inventive concept will be described in detail with reference to the attached drawings. Like reference numerals in the drawings denote like elements and repetitive descriptions will be omitted.

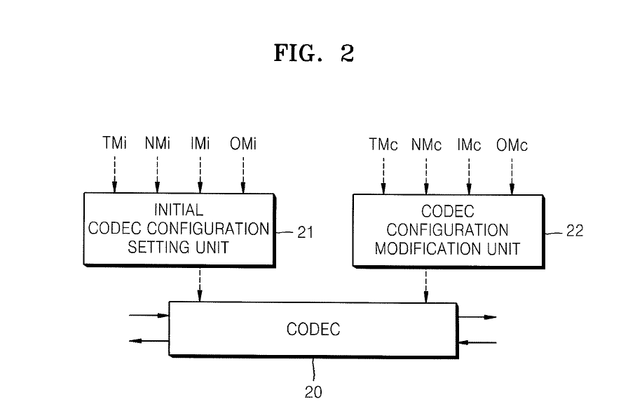

FIG. 2 is a schematic diagram to describe a method of reconfiguring a codec 20 according to an exemplary embodiment of the present general inventive concept. In FIG. 2, dotted lines represent control signals and solid lines represent substantive data, which, as used herein, refers to the data containing the information being transmitted, such as the speech, audio and video data.

Referring to FIG. 2, an initial codec configuration setting unit 21 configures the codec 20 based on initial terminal mode (TMi) information on a terminal having the codec 20, initial network mode (NMi) information on a network in which substantive data are transmitted, initial input mode (IMi) information on input data of the codec 20, and initial output mode (OMi) information on output data of the codec 20. Examples of terminal mode information, network mode information, input mode information, and output mode information are given below.

A codec configuration modification unit 22 reconfigures the codec 20 based on real-time information of current terminal mode (TMc) information, current network mode (NMc) information, current input mode (IMc) information, and current output mode (OMc) information.

The codec 20 is initially configured by receiving at least one of the terminal mode information, the network mode information, the input mode information, and the output mode information, and is reconfigured upon receiving a real-time update value of at least one of the terminal mode information, the network mode information, the input mode information and the output mode information.

Here, a data processing system or network is configured in accordance with the number of properties of the various functional units, mutual connections, and other basic characteristics thereof. The processing system or network may be configured through processes embodied in software, hardware or both.

The codec 20 may be variably configured by controlling quality of service (QoS) parameters such as, for example, quality, bit rate, complexity, delay, amount of bits allocated for error protection, encoding mode, number of encoding channels, number of decoding channels, and frame size, among others. In order to reconfigure the codec 20 in accordance with the QoS parameters, the performance of the network and states of services are measured. For example, a QoS monitoring process may be used to effectively measure and analyze quality of services provided by the network in order to evaluate whether the services properly satisfy the quality requirements. The result of QoS monitoring may be fed back and be used to modify the existing configuration of the network.

The quality referred to herein may be the perceivable audio or video quality, and when the quality is high, a higher performance level of the codec 20 is required. The bit rate refers to transmission speed of a media signal, that is, an amount of data per unit time used to encode the media signal. When the bit rate is high, the quality of the media signal is improved, but the occupancy of the channel to transmit the media signal increases. Here, the media signal may include speech, music, and video signals. The complexity is a degree of how complex the coding/decoding processes of the codec 20 must be to meet the quality, and when the complexity is low, the codec 20 is less computationally burdened. The delay is a degree to which the media signal is delayed in the network, and when the delay is low, the performance of the codec 20 is more efficient. The amount of bits allocated for error protection is an amount of additional data inserted into the transmitted data in order to recover the data in the presence of errors. The additional data may be inserted in accordance with the priority of particular segments of the transmitted data, and may thus change in amount accordingly. The encoding mode can be classified into a speech mode and a music mode in accordance with a source of an input signal. The numbers of encoding and decoding channels are the numbers of channels in which encoding and decoding are performed, respectively.

Exemplary information on terminal mode, network mode, input mode, and output mode, and an exemplary method of reconfiguring a codec in accordance with the information will now be described with reference to Tables 1, 2, 3 and 4.

A method of reconfiguring a codec in accordance with a terminal mode will now be described with reference to Table 1 below, according to an exemplary embodiment of the present general inventive concept.

TABLE 1

| Configu- | | | Codec | | |
|---|---|---|---|---|---|
| ration | Configuration | | Configuration Setting | | |
| Setting | Information | Configuration | | Bit | Com- |
| Time | Category | Information | Quality | Rate | plexity |
| Initial | Terminal Type | Hand-held | Medium | NA | Low |
| Setting | | Fixed | High | NA | High |
| | Battery State | High | NA | NA | High |
| | | Medium | NA | NA | Medium |
| | | Low | NA | NA | Low |
| | User's setting | Quality | High to | NA | NA |
| | | High to Low | Low | | |
| | | Bit Rate | NA | High to | NA |
| | | High to Low | | Low | |
| | | Complexity | NA | NA | High to |
| | | High to Low | | | Low |
| Resetting | Battery State | High | NA | NA | High |
| | | Medium | NA | NA | Medium |
| | | Low | NA | NA | Low |

Referring to Table 1, the terminal mode of the codec may be configured at an initial setting time and a resetting time in accordance with a configuration setting time. As used herein, the initial setting time may be a point of time at which the codec begins to provide a service and the resetting time may be a point of time at which a predetermined time period has elapsed after the codec has begun to provide the service.

The codec may be configured by determining QoS parameters. Here, the QoS parameters applicable to the terminal mode may include quality, bit rate, and complexity.

The exemplary method of reconfiguring the codec by controlling the QoS parameters in accordance with configuration setting time and configuration information will now be described.

At the initial setting time, the codec may be configured based on the type of terminal, the battery state, and user's setting information.

The type of terminal may be classified into a hand-held device and a fixed device in accordance with the type of power supply used to provide power to the device. According to this classification, electricity is not continuously supplied to the hand-held device and thus the battery state is variable, and data transmission may be delayed. Accordingly, the quality may be set to be medium and the complexity may be set lower than a predetermined complexity threshold value. Electricity is continuously and stably supplied to the fixed device. Accordingly, the quality may be set higher than a predetermined quality threshold value and the complexity may also be set to be higher than the predetermined complexity threshold value. In this case, the bit rate is independent of the type of terminal.

In the case of the fixed terminal device, the battery state may not be considered. However, the battery state of the hand-held device is variable and has a significant effect on the operation of the codec, which can therefore be configured accordingly. The battery state may be classified into three stages by quantizing the remaining amount of battery power. If the remaining amount of battery power is sufficient, that is, if the battery state is higher than a predetermined battery threshold value, the complexity may be set to be high so that the coding/decoding process of higher complexity than the predetermined complexity threshold value may be activated. If the battery state is medium, the complexity may be set to be medium. If the remaining amount of battery is insufficient, that is, if the state of battery is lower than the predetermined battery threshold value, the complexity may be set to be low so that complexity of the coding/decoding process is lower than the predetermined complexity threshold value. In this case, the battery state is independent of the quality and the bit rate.

The user's setting may be an initial setting of the quality, the bit rate, and the complexity of the codec, as determined by a user. If the user sets the quality, the user's setting is not applicable to the bit rate and the complexity. If the user sets the bit rate, the user's setting is not applicable to the quality and the complexity. If the user sets the complexity, the user's setting is not applicable to the quality and the bit rate.

At the resetting time, the codec may be reconfigured based on the battery state. The type of terminal is not changeable and thus may not be considered at the resetting time. Furthermore, electricity is uniformly supplied to the fixed device and the power state of the fixed device does not change with time. Therefore, the codec may be reconfigured in accordance with the battery state of the hand-held device.

As in the initial setting time, if the battery state is higher than the predetermined battery threshold value, the complexity may be set to be high so that the coding/decoding process of which complexity is higher than the predetermined complexity threshold value may be activated. If the battery state is medium, the complexity may be set to be medium. If the battery state is lower than the predetermined battery threshold value, the complexity may be set to be low so that the coding/decoding complexity is lower than the predetermined complexity threshold value. In this case, the battery state is independent of the quality and the bit rate.

A method of reconfiguring a codec in accordance with a network mode will now be described with reference to Table 2 below, according to an exemplary embodiment of the present general inventive concept.

TABLE 2

| | Configuration | | Codec Configuration Setting | | | |
|---|---|---|---|---|---|---|
| Configuration | Information | Configuration | | Bit | | Error |
| Setting Time | Category | Information | Quality | Rate | Delay | Protection |
| Initial Setting | Service Type | Communication | Medium | Low | Short | High |
| | | Streaming | Medium | High | Long | Low |
| | | Broadcasting | High | High | Medium | High |
| | Network to be | Mobile Network | Medium | Low | Short | High |
| | Used | PSTN | Medium | Low | Medium | Low |
| | | IP | High | High | Short | High |
| Resetting | Error Rate | High | NA | NA | NA | High |
| | | Low | NA | NA | NA | Low |
| | Bandwidth | High | NA | High | NA | NA |
| | | Low | NA | Low | NA | NA |

Referring to Table 2, the network mode of the codec may be configured at an initial setting time and a resetting time in accordance with the time at which the codec is configured.

The network mode of the codec may be configured by determining QoS parameters. Here, the QoS parameters include quality, a bit rate, delay, and an amount of bits allocated for error protection.

The method of reconfiguring the codec by controlling the QoS parameters in accordance with configuration setting time and configuration information will now be described.

At the initial setting time, the codec may be configured based on the type of service and the type of network to be used.

The service may be a content service providing input data to the codec and may be classified into a communication service, a streaming service, and a broadcasting service. The communication service is provided in real time by, for example, telephones and Internet messaging services. In a real-time communication service, it is important to reduce delay. Thus, the delay may be set to be less than a predetermined delay threshold value, the quality may be set to be medium, the bit rate may be set lower than a predetermined bit rate threshold value, and the amount of bits allocated for error protection may be set to be higher than a predetermined ECC threshold value. The streaming service does not store media signals in a hard disk and reproduces the media signals in real time. For example, currently popular user created contents (UCC) may provide the streaming service. In the streaming service, the quality may be set to be medium, the bit rate may be set to be higher than the predetermined bit rate threshold value, the delay may be set to be longer than the predetermined delay threshold value, and the amount of bits allocated for error protection may be set to be lower than the predetermined ECC threshold value. The broadcasting service is provided to the public through, for example, electromagnetic waves over a broadcast medium. In the broadcasting service, the bit rate may be set to be higher than the predetermined bit rate threshold value, the quality may be set to be higher than the predetermined quality threshold value, the delay may be set to medium, and the amount of bits allocated for error protection may be set to be higher than the predetermined ECC threshold value.

The network to be used may be a mobile network, a public switched telephone network (PSTN), or a network operating under an Internet protocol (IP). The mobile network is a network between mobile stations and a base station. In the case of a mobile network, the quality may be set to be medium, the bit rate may be set to be lower than the predetermined bit rate threshold value, the delay may be set to be less than the predetermined delay threshold value, and the amount of bits allocated for error protection may be set to be higher than the predetermined ECC threshold value. The PSTN may be operated by a public communication operator. In the case of a PSTN, the quality may be set to be medium, the bit rate may be set to be lower than the predetermined bit rate threshold value, the delay may be set to be medium, and the amount of bits allocated for error protection may be set to be lower than the predetermined ECC threshold value. IP is a protocol used in transmitting data from a computer to another computer over the Internet. In the case of an IP network, the quality and the bit rate may be set to be higher than the predetermined quality and bit rate threshold values, respectively, the delay may be set to be less than the predetermined delay threshold value, and the amount of bits allocated for error protection may be set to be higher than the predetermined ECC threshold value.

At the resetting time, the codec may be reconfigured as to the error rate and bandwidth of the network.

The error rate may be classified into two stages by quantizing errors occurring in a current network. If the error rate is higher than a predetermined error rate threshold value, the amount of bits allocated for error protection may be set to be higher than the predetermined ECC threshold value. If the error rate is lower than the predetermined threshold value, the amount of bits allocated for error protection may be set to be lower than the predetermined ECC threshold value.

A method of reconfiguring a codec in accordance with an input mode will now be described with reference to Table 3 below, according to an exemplary embodiment of the present general inventive concept.

TABLE 3

| | | | Codec Configuration | |
|---|---|---|---|---|
| | | | Setting | |
| | Configuration | | | Number of |
| Configuration | Information | Configuration | Encoding | Encoding |
| Setting Time | Category | Information | Mode | Channels |
| Initial Setting | Number of | 1 | NA | 1 |
| | Channels | 2 | NA | 2 |
| | | ≧3 | NA | ≧3 |
| | Initial Source | Speech | Speech | NA |
| | Mode | Music | Music | NA |
| Resetting | Number of | 1 | NA | 1 |
| | Current | 2 | NA | 2 |
| | Channels | ≧3 | NA | ≧3 |
| | Current Source | Speech | Speech | NA |
| | Mode | Music | Music | NA |

Referring to Table 3, the input mode of the codec may be classified at an initial setting time and a resetting time in accordance with the configuration setting time.

The codec may be configured by determining QoS parameters. Here, the exemplary QoS parameters applicable to the input mode include an encoding mode and the number of encoding channels.

The method of reconfiguring the codec by controlling the QoS parameters in accordance with configuration setting time and configuration information will now be described.

At the initial setting time, the codec may be configured based on the number of channels and a source mode.

The number of channels may be 1 through N. Here, N is a natural number. If the number of channels is one (a mono channel), the number of encoding channels may also be set to be one. If the number of channels is two (stereo channels), the number of encoding channels may also be set to be two. If the number of channels is equal to or greater than three, the number of encoding channels may also be set to be equal to or greater than three. In this case, the number of channels is independent of the encoding mode.

The source mode may be classified into a speech mode and a music mode. If a media signal is a speech signal, the encoding mode may also be set to be the speech mode. If the media signal is a music signal, the encoding mode may also be set to be the music mode. In this case, the source mode is independent of the number of encoding channels.

At the resetting time, the codec may be reconfigured based on the number of current channels and a current source mode.

The number of current channels may be 1 through N, where N is a natural number. If the number of current channels is one (a mono channel), the number of encoding channels may also be set to be one. If the number of current channels is two (stereo channels), the number of encoding channels may also be set to be two. If the number of current channels is equal to or greater than three, the number of encoding channels may also be set to be equal to or greater than three. In this case, the number of current channels is independent of the encoding mode.

The current source mode may be classified into a speech mode and a music mode. If a current media signal is a speech signal, the encoding mode may also be set to be the speech mode. If the current media signal is a music signal, the encoding mode may also be set to be the music mode. In this case, the current source mode is independent of the number of encoding channels.

A method of reconfiguring a codec in accordance with an output mode will now be described with reference to Table 4 below, according to an embodiment of the present general inventive concept.

TABLE 4

| | | | Codec | |
|---|---|---|---|---|
| | | | Configuration | |
| | | | Setting | |
| | Configuration | | | Number of |
| Configuration | Information | Configuration | | Decoding |
| Setting Time | Category | Information | Quality | Channels |
| Initial Setting | Number of | 1 | NA | 1 |
| | Output | 2 | NA | 2 |
| | Channels | ≧3 | NA | ≧3 |
| | Output Device | Earphone/Handset | Medium | 1 |
| | | Headset | High | 2 |
| | | Loud Speaker | High | ≧1 |
| Resetting | Number of | 1 | NA | 1 |
| | Current Output | 2 | NA | 2 |
| | Channels | ≧3 | NA | ≧3 |
| | Current Output | Earphone/Handset | Medium | 1 |
| | Device | Headset | High | 2 |
| | | Loud Speaker | High | ≧1 |

Referring to Table 4, the output mode may be configured at initial setting time and a resetting time in accordance with the configuration setting time.

The codec may be configured by determining QoS parameters. Here, the QoS parameters applicable to the output mode include quality and the number of decoding channels.

The method of reconfiguring the codec by controlling the QoS parameters in accordance with configuration setting time and configuration information will now be described.

At the initial setting time, the codec may be configured based on the number of channels and an output device.

The number of channels may be 1 through N, where N is a natural number. If the number of channels is one (a mono channel), the number of decoding channels may also be set to be one. If the number of channels is two (stereo channels), the number of decoding channels may also be set to be two. If the number of channels is equal to or greater than three, the number of decoding channels may also be set to be equal to or greater than three. In this case, the number of channels is independent of the quality.

The output device may be classified into an earphone/handset, a headset, and a loud speaker in accordance with the number of output terminals. In the case of an earphone/handset which has one output terminal, the quality may be set to be medium and the number of decoding channels may be set to be one. In the case of a headset which has two output terminals, the quality may be set to be high and the number of decoding channels may be set to be two. In the case of a loud speaker, which has a plurality of output terminals, the quality may be set to be high and the number of decoding channels may be set to be equal to or greater than one.

At the resetting time, the codec may be reconfigured based on the number of current channels and a current output device.

The number of current channels may be 1 through N, where N is a natural number. If the number of current channels is one (a mono channel), the number of decoding channels may also be set to be one. If the number of current channels is two (stereo channels), the number of decoding channels may also be set to be two. If the number of current channels is equal to or greater than three, the number of decoding channels may also be set to be equal to or greater than three. In this case, the number of current channels is independent of the quality.

The current output device may be classified into an earphone/handset, a headset, and a loud speaker in accordance with the number of output terminals. In the case of an earphone/handset which has one output terminal, the quality may be set to be medium and the number of decoding channels may be set to be one. In the case of a headset which has two output terminals, the quality may be set to be high and the number of decoding channels may be set to be two. In the case of a loud speaker having a plurality of output terminals, the quality may be set to be high and the number of decoding channels may be set to be equal to or greater than one, according to the number of output terminals of the loud speaker.

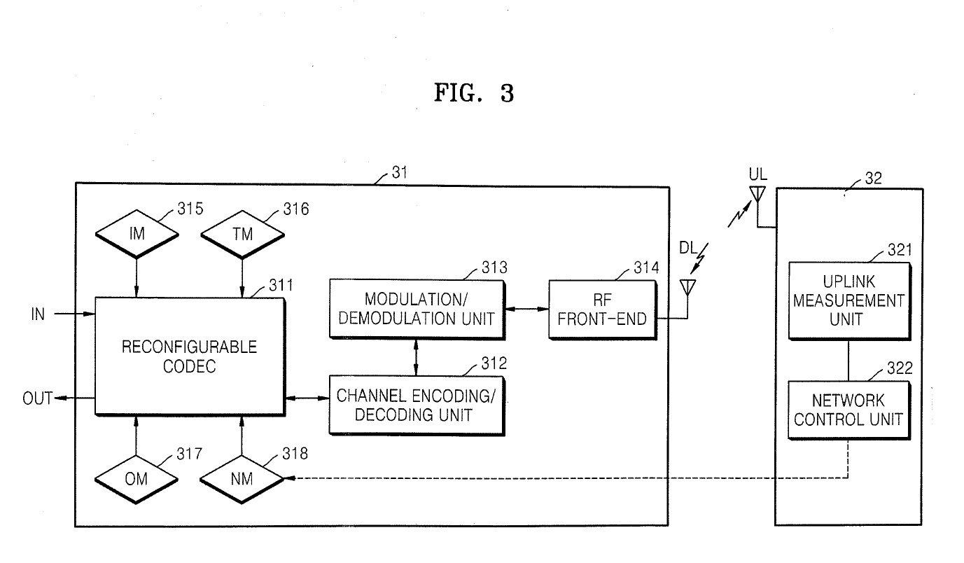

FIG. 3 is a block diagram of a system including a reconfigurable codec 311, which may operate in a similar manner as codec 20 illustrated in FIG. 2, according to an exemplary embodiment of the present general inventive concept.

Referring to FIG. 3, the system according to the current embodiment of the present general inventive concept includes a mobile station 31 and a base station 32. The mobile station 31 includes the reconfigurable codec 311, a channel encoding/decoding unit 312, a modulation/demodulation unit 313, a radio frequency (RF) front-end 314, an input mode information providing unit IM 315, a terminal mode information providing unit TM 316, an output mode information providing unit OM 317, and a network mode information providing unit NM 318. The base station 32 includes an uplink measurement unit 321 and a network control unit 322.

The reconfigurable codec 311 encodes and decodes a media signal. In more detail, the reconfigurable codec 311 may perform analog to digital (A/D) conversion and compression on a media signal. Here, the media signal may include speech, music, and video signals. According to an embodiment of the present general inventive concept, the reconfigurable codec 311 receives information from at least one of the input mode information providing unit IM 315, the terminal mode information providing unit TM 316, the output mode information providing unit OM 317, and the network mode information providing unit NM 318. The reconfigurable codec 311 controls QoS parameters based on the received information and resets its configuration in accordance with the controlled QoS parameters. The controlling of the QoS parameters based on the information received from the input mode information providing unit IM 315, the terminal mode information providing unit TM 316, the output mode information providing unit OM 317, and the network mode information providing unit NM 318 has been described above with reference to FIG. 2 and thus repeated descriptions thereof will be omitted.

The channel encoding/decoding unit 312 adds bits to the input media signal so that a receiver may detect and/or correct an error caused by noise generated in a communication channel when the media signal is transmitted and stored. In this case, the added bits are referred to as redundancies, and the receiver recovers from the error by using the redundancies transmitted with the media signal by way of a suitable ECC scheme embodied in the channel encoding/decoding unit 312.

The modulation/demodulation unit 313 converts the media signal into a signal suitable to be transmitted through a communication circuit. In more detail, the modulation/demodulation unit 313 modulates the media signal to be carried by a carrier wave. Here, the carrier wave may be a sine wave or a pulsed wave which carries information in the mobile communication system. Also, the modulation/demodulation unit 313 receives the modulated carrier wave and extracts a signal by removing carrier wave components from the modulated carrier wave. That is, the modulation/demodulation unit 313 performs demodulation so that the original signal is extracted from the modulated signal.

The RF front-end 314 pre-processes the media signal received from, for example, an antenna, provides the media signal to the modulation/demodulation unit 313, and transmits a signal output from the modulation/demodulation unit 313 to the base station 32 through the antenna and a mobile network.

The uplink measurement unit 321 of the base station 32 measures the uplink state, and more particularly, the uplink quality. The network control unit 322 provides information on the mobile network to the network mode information providing unit NM 318 of the mobile station 31 based on the network state and the uplink quality which is measured by the uplink measurement unit 321.

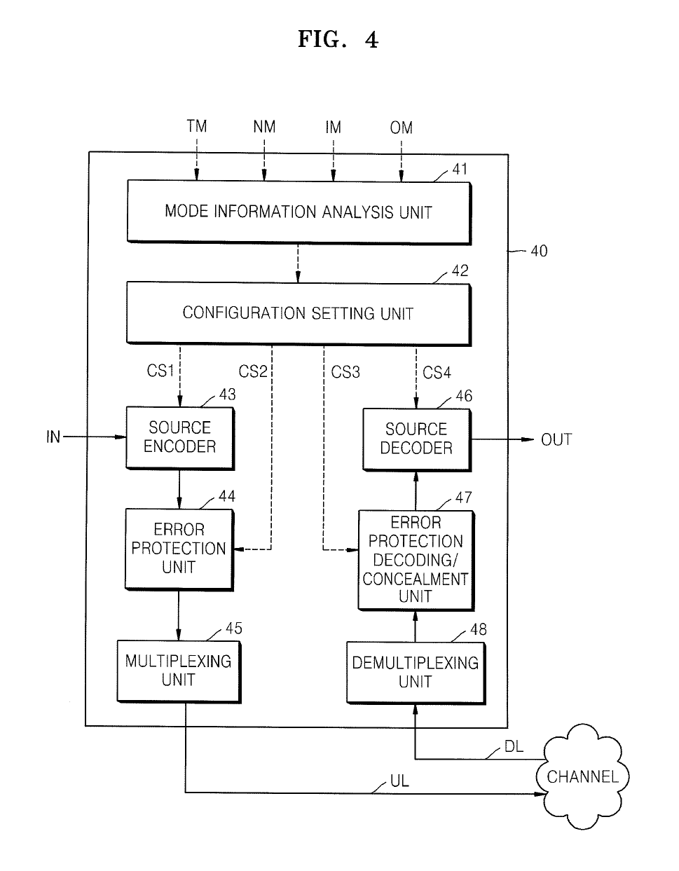

FIG. 4 is a detailed block diagram of an exemplary reconfigurable codec 40, which may be used as the reconfigurable codec 311 illustrated in FIG. 3, according to an embodiment of the present general inventive concept.

Referring to FIG. 4, the reconfigurable codec 40 according to the current embodiment of the present general inventive concept includes a mode information analysis unit 41, a configuration setting unit 42, a source encoder 43, an error protection unit 44, a multiplexing unit 45, a source decoder 46, an error protection decoding/concealment unit 47, and a demultiplexing unit 48.

The mode information analysis unit 41 receives at least one of terminal mode information TM, network mode information NM, input mode information IM, and output mode information OM, and analyzes the received information to configure the reconfigurable codec 40.

The configuration setting unit 42 controls QoS parameters of the reconfigurable codec 40 based on the information analyzed by the mode information analysis unit 41, and configures at least one of the source encoder 43, the error protection unit 44, the source decoder 46, and the error protection decoding/concealment unit 47 in accordance with the controlled QoS parameters. The exemplary configuration method as described above with reference to FIG. 2 may be implemented by the exemplary components of codec 40, and a repeated description thereof will thus be omitted.

The source encoder 43 receives an input signal IN and performs A/D conversion and compression on the input signal IN. Here, the source encoder 43 may be reconfigured by a first control signal CS1 provided from the configuration setting unit 42. For example, if the configuration setting unit 42 sets an encoding mode to be a speech mode or a music mode based on the input mode information IM, the source encoder 43 encodes the input signal IN in accordance with the setting result.

The error protection unit 44 adds parity bits and/or redundancies to the data output by the source encoder 43 to overcome an error generated during data transmission through a channel. Here, the parity bits are added to original data in order to determine whether an error is generated during data transmission. For example, the parity bits may be added to one end of the original data so that the number of bits having a value of one is always even or odd in accordance with the logic structure of the system. Here, the error protection unit 44 may be reconfigured based on a second control signal CS2 provided from the configuration setting unit 42. For example, if the configuration setting unit 42 sets an amount of bits allocated for error protection to be high or low based on the network mode information NM, the error protection unit 44 may change the number of the parity bits to be added in accordance with the setting result.

The multiplexing unit 45 generates a bitstream by using output data of the error protection unit 44 and transmits the bitstream through a corresponding transmission channel. The demultiplexing unit 48 demultiplexes the bitstream transmitted through the transmission channel.

The error protection decoding/concealment unit 47 receives output data of the demultiplexing unit 48 and recovers data that may have been corrupted by using spatial/temporal redundancy of normally received data. In more detail, the error protection decoding/concealment unit 47 may conceal errors by using a repetition method or an interpolation method. The repetition method restores a frame having errors by repeating a spectrum of a previous normal frame. The interpolation method restores the frame having errors by interpolating spectra of previous and subsequent normal frames. Here, the error protection decoding/concealment unit 47 may be reconfigured based on a third control signal CS3 provided from the configuration setting unit 42. For example, if the configuration setting unit 42 sets the amount of bits allocated for error protection to be high or low based on the network mode information NM, the error protection decoding/concealment unit 47 may appropriately apply the repetition method or the interpolation method in accordance with the setting result.

The source decoder 46 receives output data of the error protection decoding/concealment unit 47, decodes, that is, performs digital to analog (D/A) conversion on the output data, and generates an output signal OUT. Here, the source decoder 46 may be reconfigured based on a fourth control signal CS4 provided from the configuration setting unit 42. For example, if the configuration setting unit 42 sets a decoding mode to be a speech mode or a music mode based on the output mode information OM, the source decoder 46 decodes the output data of the error protection decoding/concealment unit 47 in accordance with the setting result.

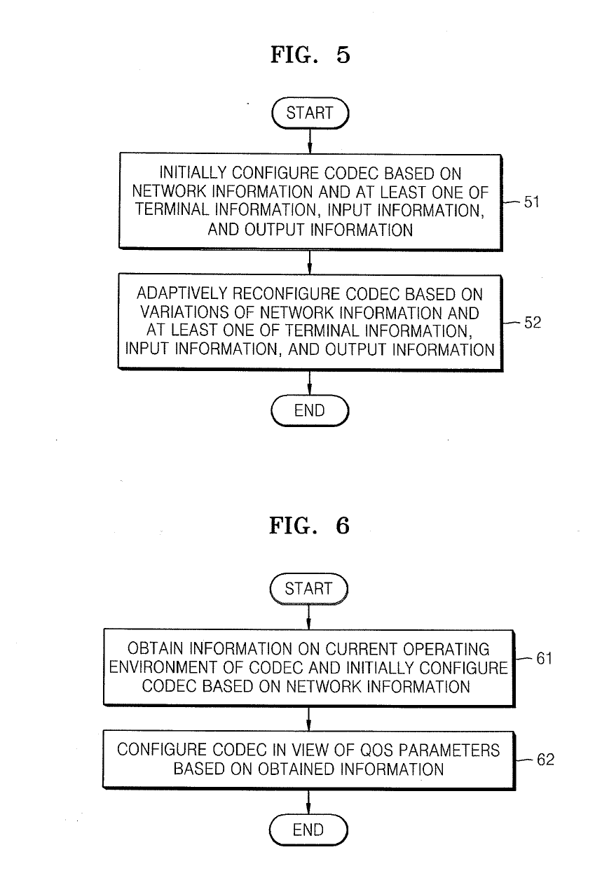

FIG. 5 is a flowchart illustrating a method of configuring a codec according to an embodiment of the present general inventive concept.

The method according to the current embodiment corresponds to the time series processing described with reference to the reconfigurable codec 40 illustrated in FIG. 4 and thus a repeated description thereof will be omitted.

Referring to FIG. 5, in operation 51, the configuration setting unit 42 illustrated in FIG. 4 initially configures the codec by determining initial values of QoS parameters based on information on a network coupled to the codec and at least one of information on a terminal having the codec, information on input data of the codec, and information on output data of the codec.

In operation 52, the configuration setting unit 42 reconfigures the codec by adaptively controlling the QoS parameters based on variations of the information on the network and at least one of the information on the terminal, the information on the input data, and the information on the output data.

FIG. 6 is a flowchart illustrating a method of configuring a codec, according to another embodiment of the present general inventive concept.

The method according to the current embodiment corresponds to the time series processing described with reference to the reconfigurable codec 40 illustrated in FIG. 4 and thus a repeated description thereof will be omitted.

Referring to FIG. 6, in operation 61, the mode information analysis unit 41 illustrated in FIG. 4 obtains information on a current operating environment of the codec. Here, the information may include at least one of information on a terminal having the codec, information on input data of the codec, information on output data of the codec, and information on a network connected to the codec.

In operation 62, the configuration setting unit 42 illustrated in FIG. 4 configures the codec in view of QoS parameters based on the obtained information.

In more detail, if the obtained information is regarding at least one of the type and the state of a power supply of the terminal having the codec, the configuration setting unit 42 may select one of at least two different types of complexity of encoding/decoding processes in accordance with the type and the state of the power supply of the terminal.

If the obtained information is regarding at least one of the number of channels and the type of a source of the input data of the codec, the configuration setting unit 42 may determine the number of encoding channels in accordance with the number of channels of the input data and determine an encoding mode to be a speech mode or a music mode in accordance with the type of the source of the input data.

If the obtained information is regarding at least one of the number of channels and the number of output terminals of the output data of the codec, the configuration setting unit 42 may determine the number of decoding channels in accordance with the number of channels of the output data and determine the quality of the output data or the number of decoding channels in proportion to the number of output terminals of the output data.

If the obtained information is regarding at least one of the type of content service providing the input data of the codec, the type and bandwidth of the network connected to the codec, and an error rate, the configuration setting unit 42 may change at least one of quality, bit rate, amount of bits allocated for error protection in accordance with at least one of the type of content service, the type and bandwidth of the network, and the error rate.

The general inventive concept can also be embodied as computer readable codes on a computer readable recording medium.

The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over a network coupled computer systems so that the computer readable code is stored and executed in a distributed fashion.

As described above, according to the present general inventive concept, a configuration of a codec may be adaptively optimized to various service environments by obtaining information on a current operating environment of the codec and configuring the codec in view of QoS parameters based on the obtained information.

Furthermore, according to the present general inventive concept, a configuration of a codec may be optimized in accordance with information on a terminal, information on input data of the codec, information on output data of the codec, and information on a network and thus data of a desired format of each service may be provided by using one codec. Therefore, the efficiency of the services may be improved.

While the present general inventive concept has been particularly illustrated and described with reference to exemplary embodiments thereof, it will be understood by those of ordinary skill in the art that various changes in form and details may be made therein without departing from the spirit and scope of the general inventive concept as defined by the appended claims. The exemplary embodiments should be considered in a descriptive sense only and not for purposes of limitation. Therefore, the scope of the general inventive concept is defined not by the detailed description of the general inventive concept but by the appended claims, and all differences within the scope will be construed as being included in the present general inventive concept.

What is claimed is:

1. A method of configuring a codec, the method comprising:
obtaining information on a current operating environment of the codec; and
configuring the codec in view of quality of service (QoS) parameters based on the obtained information.

2. The method of claim 1, wherein the information comprises at least one of information on a terminal having the codec, information on input data of the codec, information on output data of the codec, and information on a network connected to the codec.

3. The method of claim 1, wherein, if the obtained information is about at least one of the type and the state of a power supply of the terminal having the codec, the QoS parameters comprise complexity of encoding and decoding operations of the codec, and the configuring of the codec comprises selecting one of a plurality of algorithms having at least two different types of the complexity in accordance with the type and the state of the power supply of the terminal.

4. The method of claim 1, wherein, if the obtained information is about at least one of the number of channels and the type of a source of the input data of the codec, the QoS parameters comprise at least one of the number of channels and a source mode of the codec, and the configuring of the codec comprises determining the number of encoding channels in accordance with the number of channels of the input data and determining an encoding mode to be a speech mode or a music mode in accordance with the source mode of the input data.

5. The method of claim 1, wherein, if the obtained information is about at least one of the number of channels and the number of output terminals of the output data of the codec, the QoS parameters comprise at least one of the number of decoding channels and quality of the output data, and the configuring of the codec comprises determining the number of decoding channels in accordance with the number of channels of the output data and determining the quality of the output data or the number of decoding channels in proportion to the number of output terminals of the output data.

6. The method of claim 1, wherein, if the obtained information is about at least one of the type of content service providing the input data of the codec, the type and bandwidth of the network connected to the codec, and an error rate, the QoS parameters comprise at least one of quality, bit rate, amount of bits allocated for error protection, and the configuring of the codec comprises changing at least one of the quality, bit rate, amount of bits allocated for error protection in accordance with at least one of the type of content service, the type and bandwidth of the network, and the error rate.

7. A computer readable recording medium having recorded thereon a computer program for executing a method of configuring a codec, the method comprising:
obtaining information on a current operating environment of the codec; and
configuring the codec in view of quality of service (QoS) parameters based on the obtained information.

8. A method of configuring a codec, the method comprising:
initially configuring the codec by determining initial values of quality of service (QoS) parameters based on information on a network connected to the codec and at least one of information on a terminal having the codec, information on input data of the codec, and information on output data of the codec; and
reconfiguring the codec by adaptively controlling the QoS parameters based on variations of the information on the network and at least one of the information on the terminal, the information on the input data, and the information on the output data.

9. A method of configuring a codec, the method comprising:
initially configuring the codec by determining initial values of quality of service (QoS) parameters based on at least one of information on a terminal having the codec, information on input data of the codec, and information on output data of the codec; and
reconfiguring the codec by adaptively controlling the QoS parameters based on variations of at least one of the information on the terminal, the information on the input data, and the information on the output data.

10. A codec comprising:
a configuration setting unit to configure the codec in view of quality of service (QoS) parameters based on information on a current operating environment of the codec;
a source encoder to encode first data in accordance with the configuration of the codec; and
a source decoder to decode second data in accordance with the configuration of the codec.

11. The codec of claim 10, wherein the configuration setting unit configures the codec in view of the QoS parameters based on at least one of information on a terminal having the codec, information on input data of the codec, information on output data of the codec, and information on a network connected to the codec.

12. The codec of claim 10, wherein, if the information is about at least one of the type and the state of a power supply of the terminal having the codec, the QoS parameters comprise complexity of encoding and decoding operations of the codec, and the configuration setting unit selects one of a plurality of algorithms having at least two different types of the complexity in accordance with the type and the state of the power supply of the terminal.

13. The codec of claim 10, wherein, if the information is about at least one of the number of channels and the type of a source of the input data of the codec, the QoS parameters comprise at least one of the number of channels and a source mode of the codec, and the configuration setting unit determines the number of encoding channels in accordance with the number of channels of the input data and determines an encoding mode to be a speech mode or a music mode in accordance with the source mode of the input data.

14. The codec of claim 10, wherein, if the information is about at least one of the number of channels and the number of output terminals of the output data of the codec, the QoS parameters comprise at least one of the number of decoding channels and quality of the output data, and the configuration setting unit determines the number of decoding channels in accordance with the number of channels of the output data and determines the quality of the output data or the number of decoding channels in proportion to the number of output terminals of the output data.

15. The codec of claim 10, wherein, if the information is about at least one of the type of content service providing the input data of the codec, the type and bandwidth of the network connected to the codec, and an error rate, the QoS parameters comprise at least one of quality, bit rate, amount of bits allocated for error protection, and the configuration setting unit changes at least one of the quality, bit rate, amount of bits allocated for error protection in accordance with at least one of the type of content service, the type and bandwidth of the network, and the error rate.

16. The codec of claim 10, further comprising an error protection unit to add parity bits to output data of the source encoder in accordance with the configuration of the codec.

17. The codec of claim 10, further comprising an error protection decoding/concealment unit to conceal damaged data received through a channel in accordance with the configuration of the codec.

18. A method of configuring a codec in a variable operational environment, the method comprising:
determining a state of at least one characteristic of the operational environment from other than a communication link of a network that can be altered by an operation of the codec; and
modifying the operation of the codec to alter the determined characteristic to achieve a predetermined quality of service in the operational environment.

19. The method of claim 18, wherein the determining of the state of the characteristic includes determining at least one of a battery state of a mobile terminal, and the modifying of the operation of the codec includes selecting an encoding/decoding process having a computational complexity corresponding to the battery state of the mobile terminal.

20. The method of claim 18, wherein the determining of the state of the characteristic includes determining an input source type and the modifying of the operation of the codec includes setting an encoding mode to encode speech or music according to the input source type.

21. The method of claim 18, wherein the determining of the state of the characteristic includes determining a number of signal channels of the input source and the modifying of the operation of the codec includes setting the number of encoding channels according to the number of signal channels of the input source.

22. The method of claim 18, wherein the determining of the state of the characteristic includes determining an output device type and the modifying of the operation of the codec includes setting an output quality and a number of decoding channels according to the output device type.

23. The method of claim 18, wherein the determining of the state of the characteristic includes determining a number of signal channels of the output device and the modifying of the operation of the codec includes setting the number of decoding channels according to the number of signal channels of the output device.

24. The method of claim 18, further comprising:
determining of a state of a network characteristic of a network to which the codec is coupled.

25. The method of claim 24, wherein the determining of the state of the network characteristic includes determining an error rate of the network and the modifying of the operation of the codec includes setting a number of error correction code bits according to the error rate.

26. The method of claim 24, wherein the determining of the state of the network characteristic includes determining a bandwidth of the network and the modifying of the operation of the codec includes setting the bit rate of the codec according to the bandwidth of the network.

27. The method of claim 18, further comprising:
initializing the operation of the codec in accordance with at least one initial characteristic of the operational environment prior to the modifying of the operation of the codec.

28. The method of claim 27, wherein the initializing of the codec includes determining a type of terminal incorporating the codec and setting signal quality and encoding/decoding process complexity according to the determined terminal type.

29. The method of claim 27, wherein the initializing of the codec includes determining a network type and a service type of a network having the codec therein and setting a signal quality, a bit rate, a delay, and a number of error correction code bits according to the network type and the service type.

30. A codec to encode and decode signals in a variable operational environment, the codec comprising:
a mode information analysis unit to determine a state of at least one characteristic the operational environment from other than a network link that can be altered; and
a configuration setting unit to receive the state of the characteristic and generate signals to modify an operation on one of input data, output data, downlink data and uplink data according to the determined state.

31. The codec of claim 30, further comprising:
a source encoder to receive one of the signals and modify an encoding operation on the input data responsive thereto; and
a source decoder to receive one of the signals and modify a decoding operation on the output data responsive thereto.

32. The codec of claim 31, wherein the encoding operation and the decoding operation are modified as to the respective complexities thereof.

33. The codec of claim 31, wherein the encoding operation and the decoding operation are modified as to the respective signal quality, bit rate, and delay thereof.

34. The codec of claim 30, further comprising:
an error protection unit to receive one of the signals and modify an error correction code on the uplink data responsive thereto; and
an error concealment unit to recover errors on the downlink data according to the error correction code.
